(19) United States
(12) Patent Application Publication
(10) Pub. No.: US 2026/0293254 A1
(43) Pub. Date: Sep. 24, 2026

(54) SEMICONDUCTOR DEVICE AND METHOD FOR MANUFACTURING SEMICONDUCTOR DEVICE

(71) Applicants: FUJI ELECTRIC CO., LTD., Kanagawa (JP); DENSO CORPORATION, Aichi (JP)

(72) Inventor: Naoyuki OHSE, Matsumoto-city (JP)

(21) Appl. No.: 19/545,030

(22) Filed: Feb. 20, 2026

(30) Foreign Application Priority Data
Mar. 19, 2025 (JP) 2025-045198

(51) Int. Cl. H10D 62/832; H10D 62/40; H10P 14/20; H10P 52/00

(52) U.S. Cl. CPC H10D 62/8325; H10D 62/40; H10P 14/3808; H10P 52/00

(57) ABSTRACT

There is provided a semiconductor device including: a SiC substrate which has an upper surface and a lower surface; an element structure which is formed on the upper surface of the SiC substrate; a lower surface region which is exposed on at least a part of the lower surface of the SiC substrate, and which has a crystal structure different from that on an upper surface side; and a lower surface electrode which is in contact with the lower surface of the SiC substrate, in a region including at least the lower surface region, in which the lower surface region includes 3C-SiC, and a silicide layer is not formed between the lower surface electrode and the lower surface of the SiC substrate.

The contents of the following patent application(s) are incorporated herein by reference:

NO. 2025-045198 filed in JP on Mar. 19, 2025.

### BACKGROUND

### 1. TECHNICAL FIELD

The present invention relates to a semiconductor device and a method for manufacturing a semiconductor device.

### 2. RELATED ART

In the related art, a method for manufacturing a semiconductor device including the steps of roughening the state of the exposed face of a SiC substrate, and of forming an electrode on the exposed face of the roughened SiC substrate, in which the roughening step has a polishing process or a laser irradiation on the exposed face, is known (for example, refer to Patent Document 1). In addition, in a method for manufacturing a silicon carbide semiconductor device, an invention in which the metal layer is irradiated with laser light, while an external force is applied such that the silicon carbide wafer and the metal layer are planarized, to form, not a silicide layer but a carbide layer, is known (for example, refer to Patent Document 2). Further, an invention is known to obtain an ohmic contact by forming a conductive layer made of graphite on a second main surface side of the semiconductor substrate (for example, refer to Patent Document 3).

Patent Document 1: Japanese Patent Application Publication No. 2006-41248

Patent Document 2: Japanese Patent No. 6076548

Patent Document 3: Japanese Patent No. 5802333

### BRIEF DESCRIPTION OF THE DRAWINGS

FIG. 1 is a diagram showing an example of a configuration of a semiconductor device 100 according to one embodiment of the present invention.

FIG. 2 is a cross-sectional view of a semiconductor device 200 according to a comparative example.

FIG. 3 is a cross-sectional view showing a modification example of a manufacturing step of the semiconductor device 100 according to an embodiment.

FIG. 4 is a diagram showing an example of a manufacturing step of the semiconductor device 100 according to an embodiment.

FIG. 5A shows a cross-sectional view of the semiconductor device 100 in an upper surface device structure forming step S1000.

FIG. 5B shows a cross-sectional view of the semiconductor device 100 in a wafer thinning processing step S1002.

FIG. 5C shows a cross-sectional view of the semiconductor device 100 in a laser annealing step S1004.

FIG. 5D shows a cross-sectional view of the semiconductor device 100 in a surface etching step S1006.

FIG. 5E shows a cross-sectional view of the semiconductor device 100 in a lower surface electrode forming step S1008.

FIG. 6 is a diagram showing a manufacturing step of the semiconductor device 200 according to the comparative example.

FIG. 7A shows a cross-sectional view of the semiconductor device 200 in the upper surface device structure forming step S1000.

FIG. 7B shows a cross-sectional view of the semiconductor device 200 in the wafer thinning processing step S1002.

FIG. 7C shows a cross-sectional view of the semiconductor device 200 in an ohmic metal deposition step S1004.

FIG. 7D shows a cross-sectional view of the semiconductor device 200 in a laser annealing step S1006.

FIG. 7E shows a cross-sectional view of the semiconductor device 200 in a surface etching step S1008.

FIG. 7F shows a cross-sectional view of the semiconductor device 200 in a lower surface electrode forming step S1010.

FIG. 8 shows an example of a schematic diagram of a lower surface 23 of a SiC substrate 11.

FIG. 9A is an example of a cross-sectional view at a position 1 in the vicinity of the lower surface 23 in FIG. 8.

FIG. 9B is an example of a cross-sectional view at a position 2 in the vicinity of the lower surface 23 in FIG. 8.

FIG. 9C is an example of a cross-sectional view at a position 3 in the vicinity of the lower surface 23 in FIG. 8.

### DESCRIPTION OF EXEMPLARY EMBODIMENTS

The present invention will be described below through embodiments of the invention, but the following embodiments do not limit the invention according to the claims. Further, not all of combinations of features described in the embodiments are essential to the solving means of the invention. In the present specification, the same parts in each figure are denoted by the same signs and numerals, and the descriptions thereof may be omitted. In addition, for convenience of description, some configurations may not be illustrated.

In the present specification, one side in a direction parallel to a depth direction of a semiconductor substrate or a semiconductor device is referred to as an "upper" side and another side is referred to as a "lower" side. One surface of two principal surfaces of a substrate, a device, a layer, or another member is referred to as an upper surface, and another surface is referred to as a lower surface. "Upper" and "lower" directions are not limited to a direction of gravity, or a direction in which a semiconductor device is mounted. In the present specification, when an upper surface side or a lower surface side is referred to, it refers to a region from the center in the depth direction of the semiconductor substrate or the semiconductor device to the upper surface or to the lower surface.

In the present specification, technical matters may be described using an orthogonal coordinate system of an X axis, a Y axis, and a Z axis. The orthogonal coordinate system merely specifies relative positions of components, and does not limit a particular direction. For example, a Z axis direction is not limited to showing a height direction with respect to the ground. It should be noted that a +Z axis direction and a -Z axis direction are directions opposite to each other. When the Z axis direction is described without describing the signs, it means that the direction is parallel to a +Z axis and a -Z axis.

In the present specification, orthogonal axes parallel to the upper surface and the lower surface of the semiconductor substrate or the semiconductor device are referred to as the X axis and the Y axis. In addition, an axis perpendicular to the upper surface and the lower surface is referred to as the Z axis. In the present specification, the Z axis direction may be referred to as a depth direction.

When a term such as “same” or “equal” is used herein, it may encompass a case where an error due to a variation in manufacturing or the like is included. The error is, for example, within 10%.

In the present specification, a conductivity type of a doping region doped with impurities is described as a P type or an N type. In the present specification, the impurities may particularly mean either donors of the N type or acceptors of the P type and may be described as dopants. In the present specification, doping means introducing the donor or the acceptor into the semiconductor substrate and turning it into a semiconductor presenting a conductivity type of the N type, or a semiconductor presenting a conductivity type of the P type.

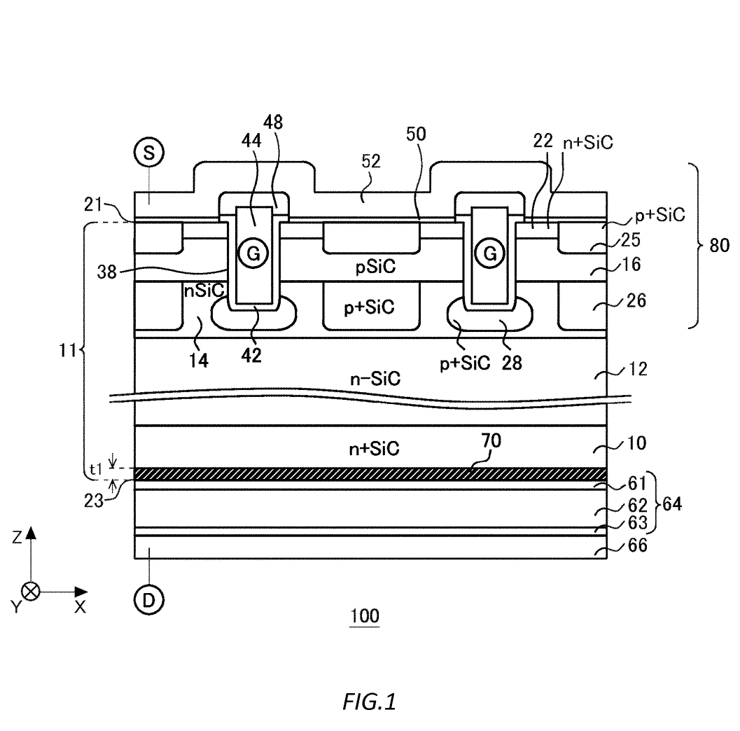

FIG. 1 is a diagram showing an example of a configuration of a semiconductor device 100 according to one embodiment of the present invention. The semiconductor device 100 of the present example is a silicon carbide semiconductor device. The semiconductor device 100 may be a vertical device in which a main current flows between an upper surface and a lower surface of the semiconductor device 100. The semiconductor device 100 of the present example is a vertical MOSFET (Metal Oxide Semiconductor Field Effect Transistor). Note that the semiconductor device 100 is not limited to this. The semiconductor device 100 may be a diode.

FIG. 1 is a cross-sectional view showing a part of the semiconductor device 100 taken along an XZ plane. In the present specification, a positive direction of the Z axis direction refers to the "upper" side, and a negative direction of the Z axis direction refers to the "lower" side. The semiconductor device 100 of the present example includes a silicon carbide substrate layer 10, a silicon carbide layer 12, a high concentration region 14, a base layer 16, an upper surface electrode 50, an upper surface electrode pad 52, a lower surface electrode 64, and a lower surface electrode pad 66.

A crystal structure of the silicon carbide substrate layer 10 may be a 4H-SiC crystal structure. The silicon carbide substrate layer 10 may be a so-called m-plane silicon carbide substrate. An m-axis direction of the silicon carbide substrate layer 10 may be parallel to the Z axis direction. The silicon carbide substrate layer 10 may also be a so-called Si-plane silicon carbide substrate. A Si-axis direction of the silicon carbide substrate layer 10 may be parallel to the Z axis direction. The silicon carbide substrate layer 10 may be a so-called C-plane silicon carbide substrate. A C-axis direction of the silicon carbide substrate layer 10 may be parallel to the Z axis direction. The silicon carbide substrate layer 10 may be a so-called a-plane silicon carbide substrate. An a-axis direction of the silicon carbide substrate layer 10 may be parallel to the Z axis direction. In addition, the silicon carbide substrate layer 10 may have a threading dislocation density of less than 1 × 10⁷ cm⁻². The silicon carbide substrate layer 10 of the present example is a substrate of an n+ type.

The silicon carbide layer 12 is a silicon carbide layer of an n- type which has an impurity concentration lower than that of the silicon carbide substrate layer 10. The silicon carbide layer 12 is a drift layer of an n type with a low concentration. The silicon carbide layer 12 is provided at an upper surface of the silicon carbide substrate layer 10. The silicon carbide layer 12 may be deposited by the epitaxial growth. On the opposite side of the silicon carbide layer 12 from a silicon carbide substrate layer 10 side, the high concentration region 14 is formed. The high concentration region 14 is a silicon carbide layer of the n type which has an impurity concentration lower than that of the silicon carbide substrate layer 10 and has an impurity concentration higher than that of the silicon carbide layer 12. The high concentration region 14 of the present example is a drift layer of the n type with a high concentration. The high concentration region 14 may be deposited by the epitaxial growth, or may be formed by doping by ion implantation. On the opposite side of the high concentration region 14 from a silicon carbide layer 12 side, the base layer 16 is formed. The base layer 16 of the present example is of a p type. The base layer 16 may be deposited by the epitaxial growth, or may be formed by doping by ion implantation.

In the present example, the silicon carbide substrate layer 10, the silicon carbide layer 12, the high concentration region 14, and the base layer 16 are collectively referred to as a SiC substrate 11. When another region is provided between the base layer 16 and the upper surface electrode 50, the other region may also be included in the SiC substrate 11. In other words, the SiC substrate 11 refers to the semiconductor substrate and the semiconductor layer between the upper surface electrode 50 and the lower surface electrode 64. The semiconductor device 100 includes the SiC substrate 11. The SiC substrate 11 has an upper surface 21 and a lower surface 23. The upper surface electrode 50 is provided in contact with the upper surface 21 of the SiC substrate 11, and functions as a source electrode. The lower surface electrode 64 is provided in contact with the lower surface 23 of the SiC substrate 11, and functions as a drain electrode.

A trench structure is formed at the upper surface 21 of the SiC substrate 11. Specifically, a trench 38 is formed from the upper surface 21 toward the inside of the SiC substrate 11. The trench 38 penetrates the base layer 16 from the upper surface (an upper surface 21 side of the SiC substrate 11) on the opposite side of the base layer 16 from the silicon carbide substrate layer 10 side, and reaches the high concentration region 14. A gate dielectric film 42 is formed, along an inner wall of the trench 38, on a bottom portion and a side wall of the trench 38. The gate dielectric film 42 may be a silicon dioxide layer, or may be formed by high temperature oxidation (HTO). Further, a gate electrode 44 is formed inside the gate dielectric film 42 in the trench 38. The gate electrode 44 is, for example, formed of polysilicon. By the gate dielectric film 42, the gate electrode 44 is insulated from the high concentration region 14 and the base layer 16. A part of the gate electrode 44 may protrude toward an upper surface electrode pad 52 side from above the trench 38. In addition, an interlayer dielectric film 48 may be formed on the gate electrode 44. The interlayer dielectric film 48 insulates the gate electrode 44 and the upper surface electrode pad 52.

A source region 22 and a contact region 25 are selectively provided, between the base layer 16 and the upper surface 21 of the SiC substrate 11. The source region 22 and the contact region 25 may be in contact with the upper surface electrode 50. In addition, the source region 22 may be in contact with the trench 38. In the present example, the source region 22 is of the n+ type, and the contact region 25 is of a p+ type. The source region 22 and the contact region 25 may be formed by doping.

A first base region 26 and a second base region 28 are selectively provided in the high concentration region 14 of the present example. A lower end portion of the first base region 26 is positioned closer to a lower surface electrode 64 side than the bottom portion of the trench 38. A lower end portion of the second base region 28 is positioned closer to the lower surface electrode 64 side than the bottom portion of the trench 38. The second base region 28 is formed at a position facing the bottom portion of the trench 38 in the depth direction (Z axis direction). A width of the second base region 28 in an X axis direction may be greater than a width of the trench 38 in the X axis direction. The bottom portion of the trench 38 may reach the second base region 28, or may be positioned in the high concentration region 14 sandwiched between the base layer 16 and the second base region 28 so as not to contact the second base region 28. In the present example, the bottom portion of the trench 38 reaches the second base region 28. In the present example, the first base region 26 and the second base region 28 are of the p+ type. In the first base region 26 and the second base region 28, for example, an aluminum element is doped.

By supplying a predetermined positive potential to the gate electrode 44, a charge inversion region (that is, a channel) is formed in the base layer 16. When a predetermined potential difference is formed between the upper surface electrode 50 (upper surface electrode pad 52) and the lower surface electrode 64 (lower surface electrode pad 66), the electron current flows from the upper surface electrode 50 to the lower surface electrode 64 through the channel.

In the present specification, a structure formed on the upper surface 21 of the SiC substrate 11 is referred to as an element structure 80. In a case of the present example, the trench 38, the high concentration region 14, the base layer 16, the source region 22, the contact region 25, and the upper surface electrode 50 are included in the element structure 80. That is, between two principal surfaces of the SiC substrate 11, the surface on which the element structure 80 is formed is the upper surface 21. When the semiconductor device 100 is not a MOSFET of a trench type, the element structure 80 may refer, for example, to a gate structure, or may refer to an anode region in the diode.

The semiconductor device 100 of the present example includes a lower surface region 70. The lower surface region 70 is a region which is exposed on at least a part of the lower surface 23 of the SiC substrate 11, and which has a crystal structure different from that of a region of the SiC substrate 11 on the upper surface 21 side. In FIG. 1, the lower surface region 70 is hatched. The lower surface region 70 of the present example is exposed over the entire lower surface 23 of the SiC substrate 11. The lower surface region 70 may be exposed on 60% or more of the lower surface 23 of the SiC substrate 11, may be exposed on 80% or more, or may be exposed on 90% or more.

The lower surface region 70 may include 3C-SiC as a crystal structure. The entire lower surface region 70 may have a 3C-SiC crystal structure. Note that the lower surface region 70 may include the crystal structure other than the 3C-SiC crystal structure. The lower surface region 70 may include, as an example, a thin layer of amorphous SiC or amorphous Si between 3C-SiC and the lower surface 23. In the lower surface region 70, the volume ratio of the 3C-SiC crystal structure may be 50% or more, may be 70% or more, or may be 90% or more.

The crystal structure of the SiC substrate 11 on the upper surface 21 side relative to the lower surface region 70 includes the 4H-SiC crystal structure. That is, the crystal structure of the silicon carbide substrate layer 10 may be the 4H-SiC crystal structure, or the crystal structure of the SiC substrate 11 on the upper surface 21 side may be the 4H-SiC crystal structure. The crystal structure of the SiC substrate 11 on the upper surface 21 side may be the 4H-SiC crystal structure by 80% or more, or may be the 4H-SiC crystal structure entirely. The crystal structure described above may be the 4H-SiC crystal structure of a single crystal. In other words, the lower surface region 70 may be a region in which the crystal structure other than the 4H-SiC crystal structure of the single crystal is formed.

The lower surface electrode 64 is in contact with the lower surface 23 of the SiC substrate 11. The lower surface electrode 64 is in contact with the lower surface 23 of the SiC substrate 11, in a region including at least the lower surface region 70. The lower surface electrode 64 may be in contact with the entire lower surface 23 of the SiC substrate 11.

The lower surface electrode 64 may have a stacked structure. The lower surface electrode 64 of the present example has a stacked structure of a Ti layer 61, a Ni layer 62, and an Au layer 63 from a lower surface 23 side of the SiC substrate 11. Ti and 3C-SiC form an ohmic contact, and thus it is possible to form the ohmic contact between the lower surface electrode 64 and the SiC substrate 11 without using a silicide layer which will be described below.

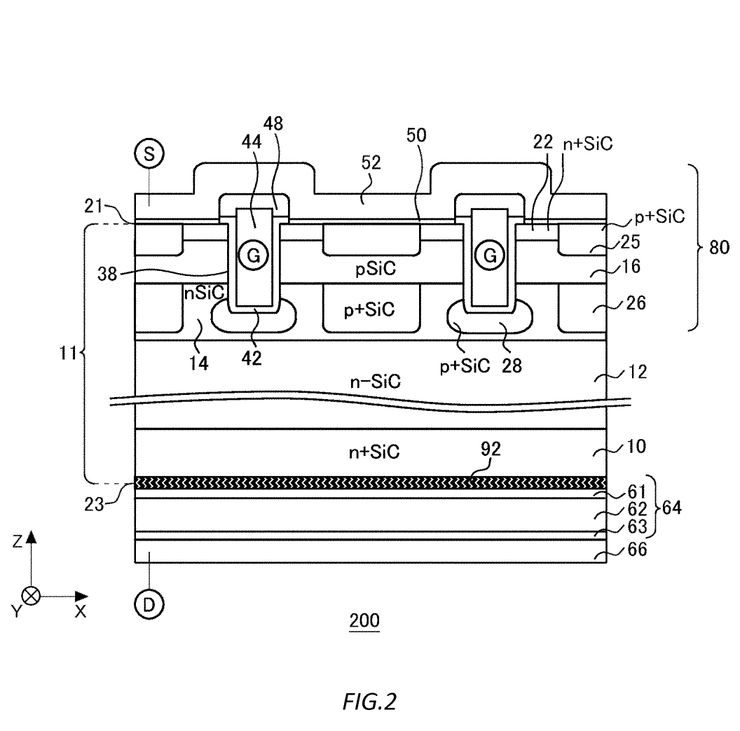

FIG. 2 is a cross-sectional view of a semiconductor device 200 according to a comparative example. In the semiconductor device 200, the lower surface region 70 is not formed, and a silicide layer 92 is formed between the SiC substrate 11 and the lower surface electrode 64. The silicide layer 92 is formed by depositing ohmic metal at the lower surface 23 of the SiC substrate 11 in a manufacturing step and causing silicidation. In the semiconductor device 200, the lower surface electrode 64 is formed at a surface of the silicide layer 92. Another portion is similar to the semiconductor device 100. The silicide layer 92 is, as an example, nickel (Ni) silicide.

A low resistance ohmic contact can be obtained at a contact interface between 4H-SiC and Ni silicide. Therefore, the silicon carbide substrate layer 10 having the 4H-SiC crystal structure and the silicide layer 92 which is Ni silicide form the low resistance ohmic contact.

However, there is a layer including carbon precipitated due to silicidation between the silicon carbide substrate layer 10 and the silicide layer 92, and thus there is a risk of delamination. Further, when high temperature processing is performed in a state in which Ni silicide is in contact with the Ti layer 61 of the lower surface electrode 64, Ni in Ni silicide diffuses into the Ti layer 61, and a void is formed in Ni silicide, and thus there is a risk of delamination.

In the semiconductor device 100 of the present example shown in FIG. 1, the silicide layer 92 is not formed between the lower surface electrode 64 and the lower surface 23 of the SiC substrate 11. Therefore, the lower surface electrode 64 is less likely to undergo delamination than in the comparative example. That is, in the semiconductor device 100, it is possible to form the ohmic contact with a reduced risk of delamination.

A thickness of the lower surface region 70 in the depth direction in FIG. 1 is set as t1. The thickness t1 may be 10 nm or more and 500 nm or less. When the thickness t1 becomes smaller than 10 nm, it is not possible to form the ohmic contact. On the other hand, an upper limit of the thickness t1 is defined by a thickness t2 of a crushed layer which will be described below. The thickness t1 may be an average value of the thickness of the lower surface region 70 over the entire lower surface region 70. The thickness t1 may be 30 nm or more, or may be 50 nm or more, and may be 100 nm or less, or may be 200 nm or less.

The thickness t1 of the lower surface region 70 may be uniform throughout the entire lower surface region 70, or may have variation in a plane. A maximum value of the thickness t1 of the lower surface region 70 in the depth direction may be three times or less of a minimum value of the thickness t1. This makes it possible to form the uniform ohmic contact. An area of the lower surface region 70, where the maximum value of the thickness t1 is three times or less of the minimum value of the thickness t1, may account for 80% or more, may account for 90% or more, or may account for 100%.

In FIG. 1, Ni is not present in a portion in contact with the lower surface region 70. The lower surface electrode 64 of the present example has the Ni layer 62, but a layer on the lower surface 23 side is the Ti layer 61, and the Ti layer 61 is in direct contact with the lower surface region 70. Therefore, Ni is not present at an interface between the lower surface region 70 and the lower surface electrode 64.

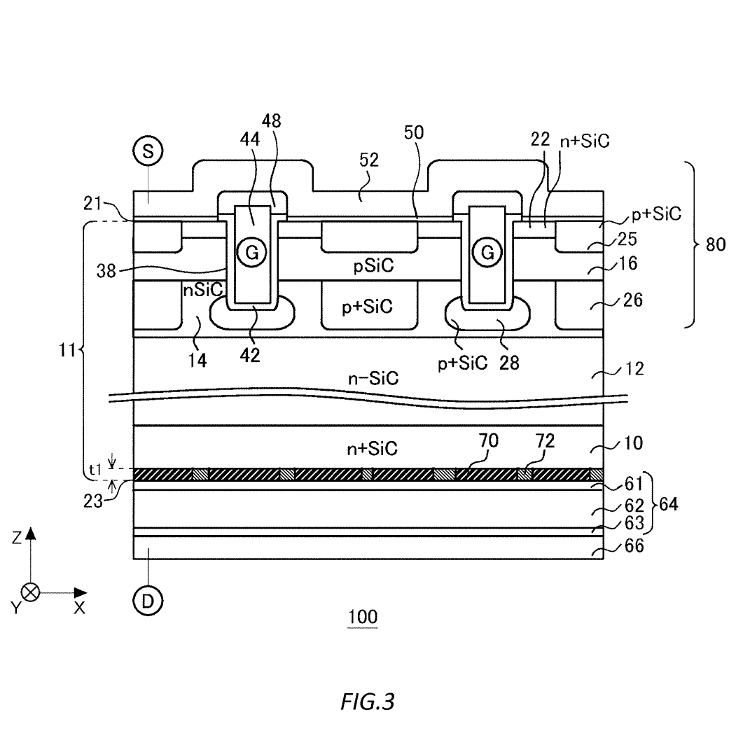

FIG. 3 is a cross-sectional view showing a modification example of a manufacturing step of the semiconductor device 100 according to an embodiment. The semiconductor device 100 of the present example has a crushed layer 72. Therefore, an arrangement of the lower surface region 70 is different in comparison with that of the semiconductor device 100 shown in FIG. 1. Another point is similar to that of the semiconductor device 100 shown in FIG. 1.

The crushed layer 72 of the present example is exposed on at least a part of the lower surface 23 of the SiC substrate 11. The crushed layer 72 refers to a layer in which the crystal structure of the SiC substrate 11 is disordered by back grinding in a manufacturing method which will be described below. The crushed layer 72 may be a region including amorphous SiC, or may be a region including microcrystalline SiC. When the crystal structure of the silicon carbide substrate layer 10 is a single crystal of 4H-SiC, the crushed layer 72 may be a region which is not the single crystal of 4H-SiC. In FIG. 3, the crushed layer 72 is thinly hatched.

The crushed layer 72 does not form the ohmic contact with either 4H-SiC or Ti. Therefore, it is not preferable for a large amount of the crushed layer 72 to be formed. Note that when the amount of the crushed layer 72 is small, a ratio of the lower surface region 70 becomes relatively high, and thus it is possible to form the ohmic contact. The ratio between the lower surface region 70 and the crushed layer 72 will be described below, but as an example, the area of the lower surface region 70 which is exposed on the lower surface 23 is greater than the area of the crushed layer 72 which is exposed on the lower surface 23. In the present example, the lower surface region 70 and the crushed layer 72 coexist. In addition, the thickness of the lower surface region 70 of the present example may be similar to the thickness t1 of the lower surface region 70 described in FIG. 1.

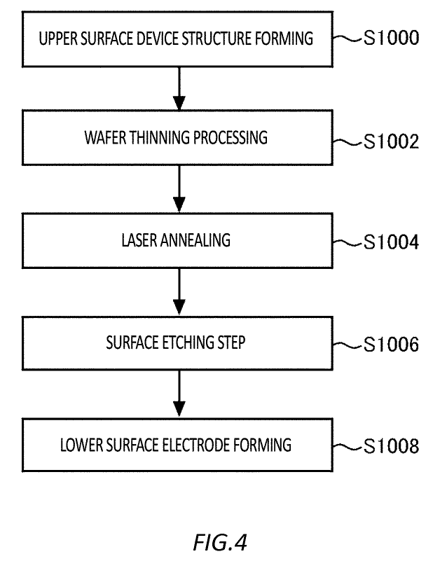

FIG. 4 is a diagram showing an example of a manufacturing step of the semiconductor device 100 according to an embodiment. The manufacturing steps of the present example include an upper surface device structure forming step S1000, a wafer thinning processing step S1002, a laser annealing step S1004, a surface etching step S1006, and a lower surface electrode forming step S1008.

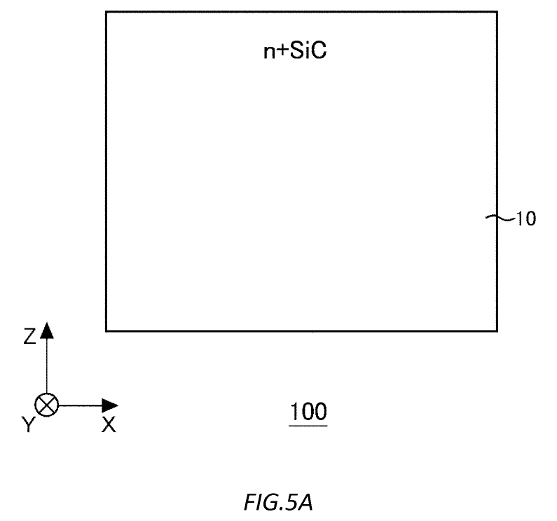

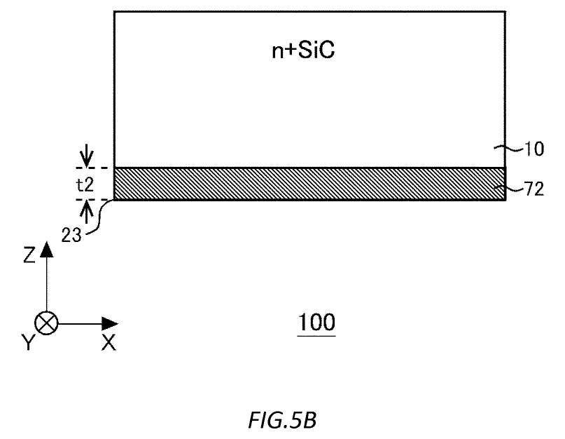

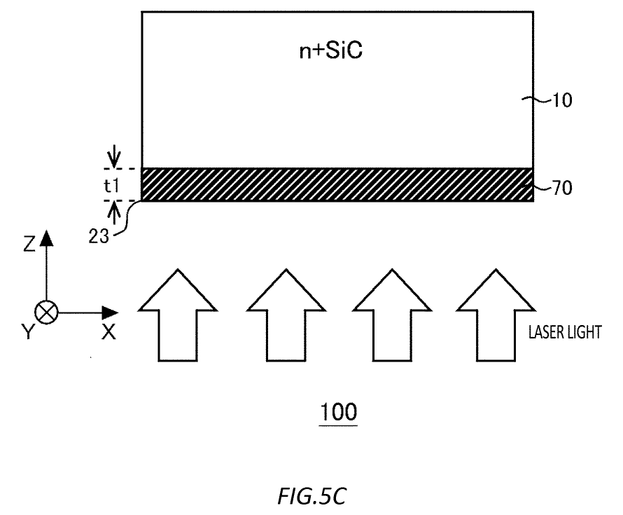

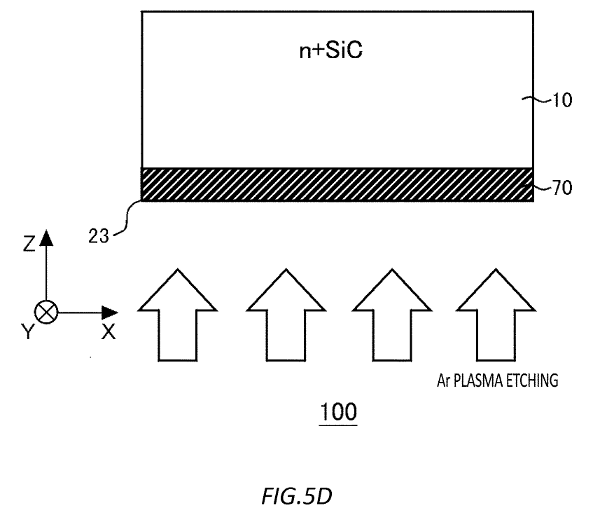

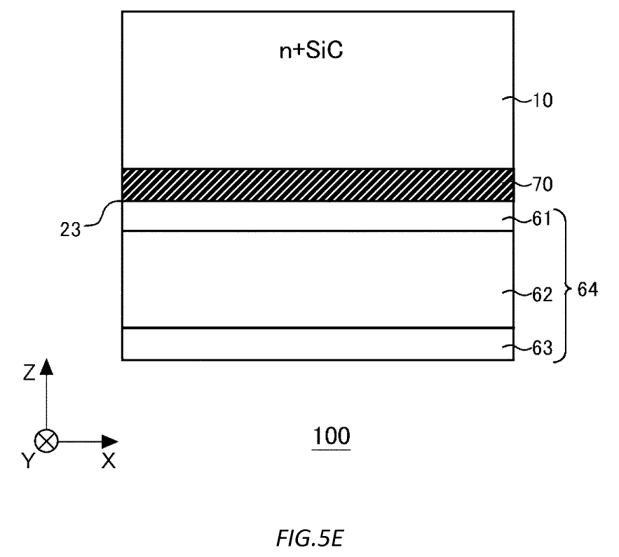

FIG. 5A to FIG. 5D respectively show cross-sectional views of the semiconductor device 100 in manufacturing steps shown in FIG. 4. Note that in FIG. 5A to FIG. 5D, the configuration on the upper surface 21 side from the silicon carbide substrate layer 10 is omitted.

FIG. 5A shows a cross-sectional view of the semiconductor device 100 in the upper surface device structure forming step S1000. In the upper surface device structure forming step S1000, for example, the element structure 80 described in FIG. 1 is formed on the upper surface 21 side. Note that in FIG. 5A, the element structure 80 is also omitted.

FIG. 5B shows a cross-sectional view of the semiconductor device 100 in the wafer thinning processing step S1002. The wafer thinning processing step S1002 is a step of performing the back grinding on the lower surface 23 of the SiC substrate 11, and thinning the SiC substrate 11. At this time, the crushed layer 72 is formed at the lower surface 23 of the SiC substrate 11. The crushed layer 72 refers to a layer in which the crystal structure of the SiC substrate 11 is disordered by the back grinding. In a case of the present example, the crushed layer 72 is a layer in which the crystal structure of the silicon carbide substrate layer 10 is disordered. As described above, the crushed layer 72 may include amorphous SiC, or may include microcrystalline SiC. When the crystal structure of the silicon carbide substrate layer 10 is a single crystal of 4H-SiC, the crushed layer 72 may include a crystal of 4H-SiC which is not a single crystal.

Typically, the crushed layer 72 is removed from the lower surface 23; however, in the present example, the crushed layer 72 remains at the lower surface 23. The crushed layer 72 which remains becomes a layer of 3C-SiC in a step described below. The thickness t2 of the crushed layer 72 before performing the laser annealing step S 1004 is, as an example, 100 nm or more and 500 nm or less. When the thickness t1 of the crushed layer 72 is too small, it is not possible to form the lower surface region 70 having the sufficient thickness. When the thickness t1 of the crushed layer 72 is too great, the crushed layer 72 ultimately remains between the lower surface region 70 and the silicon carbide substrate layer 10. The thickness t2 of the crushed layer 72 may be 200 nm or more, and may be 400 nm or less. The thickness t2 of the crushed layer may be adjusted after the back grinding so as to achieve the thickness described above. In addition, in order to achieve the thickness described above, the lower surface 23 may be ground with a grinding tool having a grain size (also referred to as grit) of #1000 or more and #10000 or less for roughness of the surface that is ground.

FIG. 5C shows a cross-sectional view of the semiconductor device 100 in the laser annealing step S1004. In the laser annealing step S1004, the laser annealing is performed on the crushed layer 72 generated by the back grinding to cause crystallization, and the lower surface region 70 is formed. The laser annealing is performed on the crushed layer 72, thereby forming the 3C-SiC crystal structure. In the present example, the lower surface region 70 is formed over the entire lower surface 23. Note that as shown in FIG. 3, the crushed layer 72 may be caused to partially remain.

In the laser annealing step S1004, the laser light is directly radiated onto the lower surface 23 of the SiC substrate 11. In other words, during the laser radiation, no metal film or the like is deposited at a surface of the lower surface 23.

On the other hand, the 4H-SiC crystal structure is comparatively stable, and even when the laser light is radiated, there is almost no change in the 3C-SiC crystal structure. By the laser annealing, the crushed layer 72 changes to have the 3C-SiC crystal structure, and the crystal structure of the silicon carbide substrate layer 10 on a side above the crushed layer 72 is maintained. Therefore, in the lower surface 23 of the SiC substrate 11, the thickness t1 of the lower surface region becomes at most equal to the thickness t2 of the crushed layer 72.

Laser intensity in the laser annealing step S1004 is, as an example, 2.4 J/cm² or more and 3.0 J/cm² or less. When the laser intensity is too low, the 3C-SiC crystal structure is not formed. On the other hand, it is confirmed that when the laser intensity is too high, the ratio of amorphous SiC or microcrystalline SiC rather increases. Therefore, it is preferable for the laser intensity to be in the range described above. A laser wavelength in the laser annealing step S1004 may be 355 nm. An atmosphere during the laser radiation may be an inert gas atmosphere with a low O₂ concentration.

FIG. 5D shows a cross-sectional view of the semiconductor device 100 in the surface etching step S1006. By the laser radiation in the laser annealing step S1004, carbon, amorphous SiC, or amorphous Si may be precipitated at a surface layer of the lower surface region 70. They may increase contact resistance between the lower surface electrode 64 and the SiC substrate 11, or cause delamination. Therefore, in the front surface etching step S1006, precipitated carbon or the like is removed by performing Ar plasma etching on the lower surface 23. Note that the front surface etching step S1006 may not be performed.

FIG. 5E shows a cross-sectional view of the semiconductor device 100 in the lower surface electrode forming step S1008. In the lower surface electrode forming step S1006, the lower surface electrode 64 is formed at the lower surface region 70. The lower surface electrode may be formed over the entire lower surface 23.

The lower surface electrode 64 may have a stacked structure. At this time, in order to form the ohmic contact with 3C-SiC of the lower surface region 70, a side of the stacked structure closest to the SiC substrate 11 may be formed of Ti. The lower surface electrode 64 of the present example has the Ti layer 61, the Ni layer 62, and the Au layer 63 from a SiC substrate 11 side, in order.

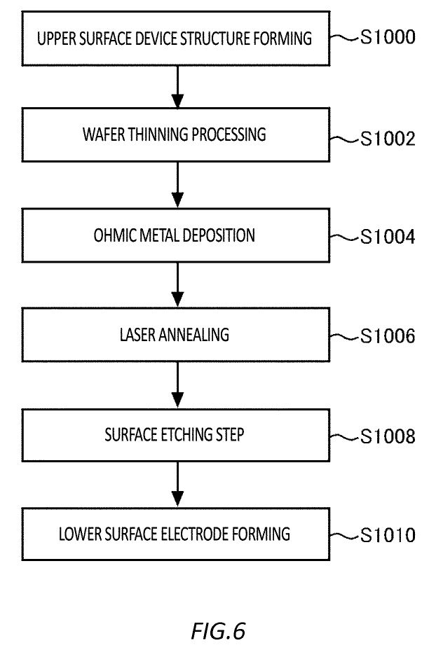

FIG. 6 is a diagram showing a manufacturing step of the semiconductor device 200 according to the comparative example. The manufacturing steps of the present example include the upper surface device structure forming step S1000, the wafer thinning processing step S1002, an ohmic metal deposition step S1004, a laser annealing step S1006, a surface etching step S1008, and a lower surface electrode forming step S1010.

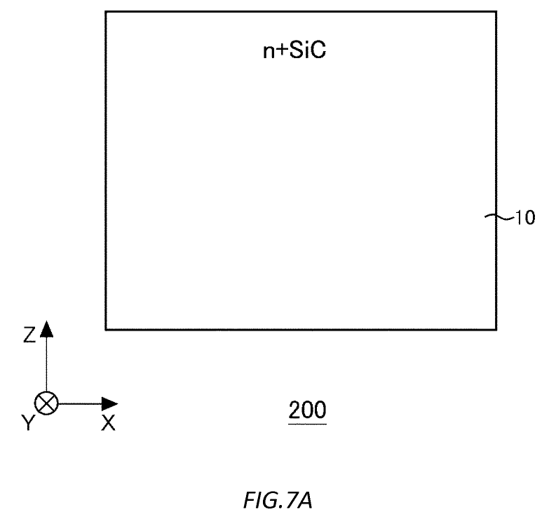

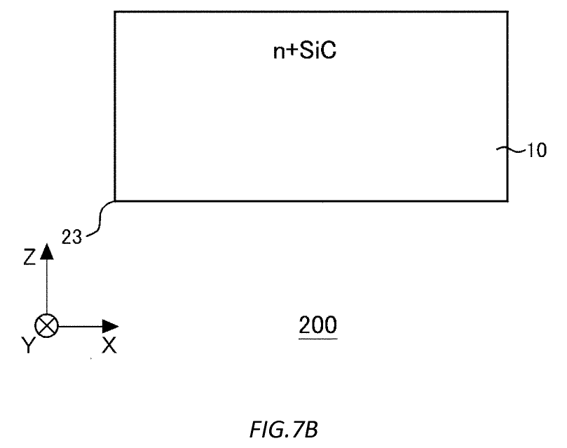

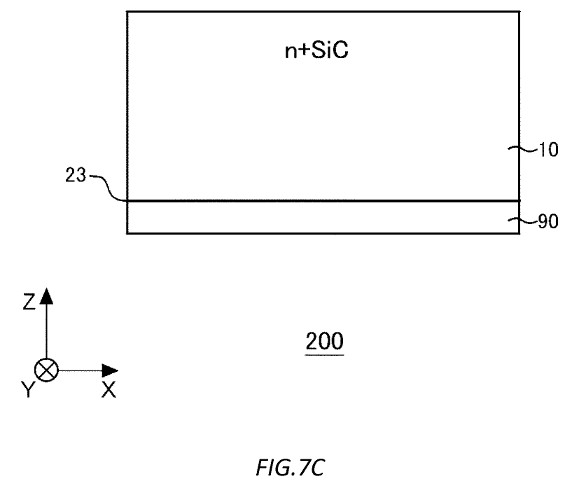

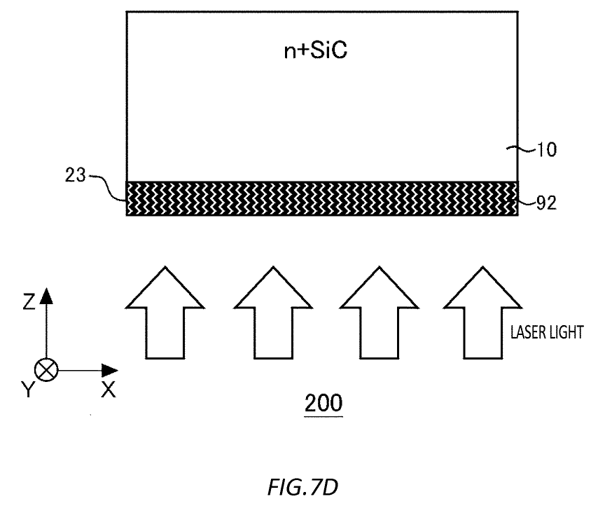

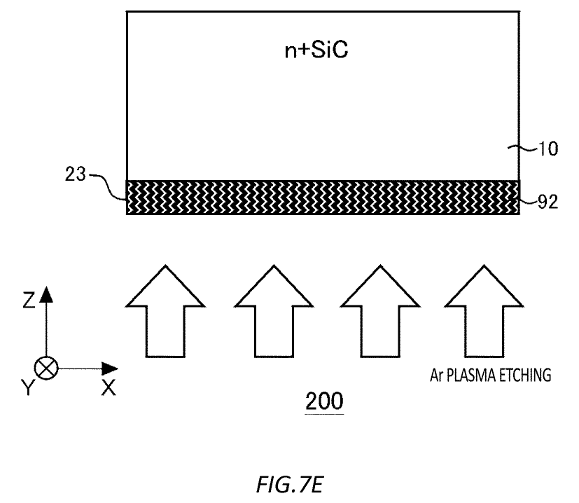

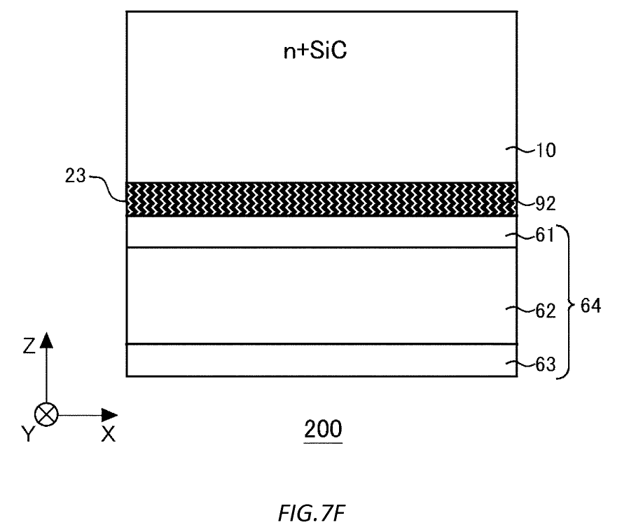

FIGS. 7A-7F respectively show cross-sectional views of the semiconductor device 200 in manufacturing steps shown in FIG. 6. Note that in FIGS. 7A-7F, the configuration on the upper surface 21 side from the silicon carbide substrate layer 10 is omitted. Description overlapping FIGS. 5A-5E will be omitted as appropriate.

FIG. 7A shows a cross-sectional view of the semiconductor device 200 in the upper surface device structure forming step S1000. The upper surface device structure forming step S 1000 of the comparative example is similar to the upper surface device structure forming step S 1000 of the semiconductor device 100.

FIG. 7B shows a cross-sectional view of the semiconductor device 200 in the wafer thinning processing step S1002. In the comparative example, the crushed layer 72 is completely removed from the lower surface 23, which is a difference from the wafer thinning processing step S1002 of the semiconductor device 100.

FIG. 7C shows a cross-sectional view of the semiconductor device 200 in the ohmic metal deposition step S1004. In the comparative example, ohmic metal 90 is deposited over the entire surface of the lower surface 23. The ohmic metal 90 is, for example, Ni.

FIG. 7D shows a cross-sectional view of the semiconductor device 200 in the laser annealing step S1006. In the comparative example, the laser light is radiated onto the ohmic metal 90 to perform the laser annealing and cause silicidation, and the metal silicide layer 92 is formed. In addition, the ohmic metal 90 may be agglomerated by the laser annealing for the SiC substrate 11 (in a case of the present example, the silicon carbide semiconductor layer 10) to be exposed on the surface. In that case, the laser light is directly radiated onto the SiC substrate 11; however, the crushed layer 72 is removed, and thus the 3C-SiC crystal structure is not formed in the semiconductor device 200.

FIG. 7E shows a cross-sectional view of the semiconductor device 200 in the surface etching step S1008. In the surface etching step S1008, carbon precipitated at the surface of the metal silicide layer 92 in the laser annealing step S1006 is etched and removed.

FIG. 7F shows a cross-sectional view of the semiconductor device 200 in the lower surface electrode forming step S1010. In the lower surface electrode forming step S1010, the lower surface electrode 64 similar to that of the semiconductor device 100 is formed.

In the semiconductor device 200 of the comparative example, the metal silicide layer 92 is formed over the entire surface of the lower surface 23. Therefore, as described above, there is a risk of delamination of the lower surface electrode 64. In addition, in a case where the ohmic metal 90 is agglomerated when the laser annealing is performed, it is not possible to form the uniform ohmic contact. In the semiconductor device 100 of the present example, it is possible to omit the step of depositing the ohmic metal 90 in the manufacturing step. Further, the crushed layer 72 which is formed in the step in the related art, is utilized, there is no need to add a new step. Even so, it is possible to form the uniform ohmic contact having high adhesion.

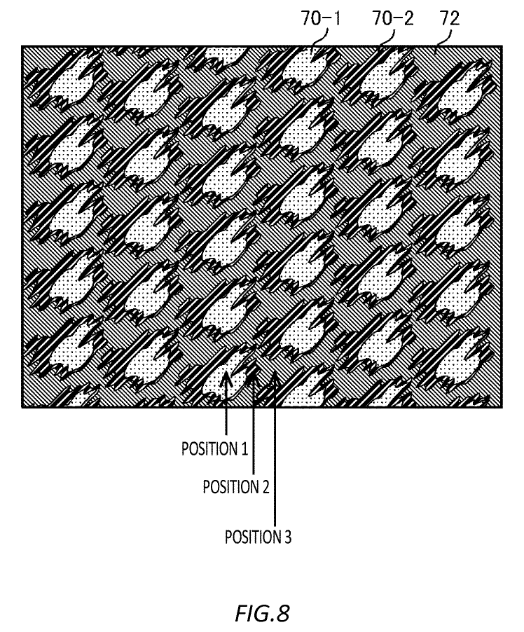

FIG. 8 shows an example of a schematic diagram of the lower surface 23 of the SiC substrate 11. FIG. 8 shows, in a bottom view after the laser annealing step S1006, the lower surface region 70 and the crushed layer 72 which are formed at the lower surface 23. In the laser annealing step S1006, laser radiation is performed while a radiation position is shifted, and thus a large number of laser radiation marks are formed at the lower surface 23.

The laser radiation positions and the periphery thereof become the lower surface region 70, because the 3C-SiC crystal structure is formed there. In the present example, the vicinity of the center position of the laser radiation is set as a lower surface region 70-1, and the periphery thereof is set as a lower surface region 70-2. The 3C-SiC crystal structure is formed at any of the lower surface regions 70. In FIG. 8, the lower surface region 70-1 is hatched differently from the lower surface region 70-2.

At a position away from the laser radiation position, the crushed layer 72 remains as it is without being transformed into 3C-SiC. That is, the crushed layer 72 of the present example is exposed on the lower surface 23, and thus the lower surface 23 of the present example is an example of the lower surface 23 of the semiconductor device 100 shown in FIG. 3. The crushed layer 72 of the present example surrounds the lower surface region in the bottom view. By forming the lower surface region 70 in a mottled pattern as in the present example, the ohmic contact portions are not localized, and it is possible to suppress current crowding.

The area of the crushed layer 72 which is exposed on the lower surface 23 of the SiC substrate 11 may be smaller than the area of the lower surface region 70 which is exposed on the lower surface 23 of the SiC substrate 11. The crushed layer 72 does not form the ohmic contact with the lower surface electrode 64 and reduces a strength (flexural strength) of the chip, and thus is preferably small in amount. The area of the crushed layer 72 which is exposed on the lower surface 23 may be 50% or less of the area of the lower surface region 70 which is exposed on the lower surface 23, may be 30% or less, may be 10% or less, or may be 5% or less. Any of the areas described above may be an area relative to the entire lower surface 23 of the SiC substrate 11. It is possible to adjust the area ratio by adjusting the radiation position of the laser light. The radiation position of the laser light may be adjusted for the laser radiation marks to overlap. It is possible to reduce the crushed layer 72 which is exposed on the lower surface by overlapping the laser radiation areas; however, a radiation time is increased, thereby lowering throughput and increasing a manufacturing cost. Therefore, with an understanding of this trade-off, it is possible to adjust a degree of laser overlap, in consideration of the delamination strength and a contact resistance value of a back surface electrode which are required for the product. It should be noted that FIG. 8 is the bottom view after the laser annealing step S1006, but the area ratio between the lower surface region 70 and the crushed layer 72 does not change in the semiconductor device 100 even after manufacturing, and thus the area ratio described above may also be applied to the semiconductor device 100.

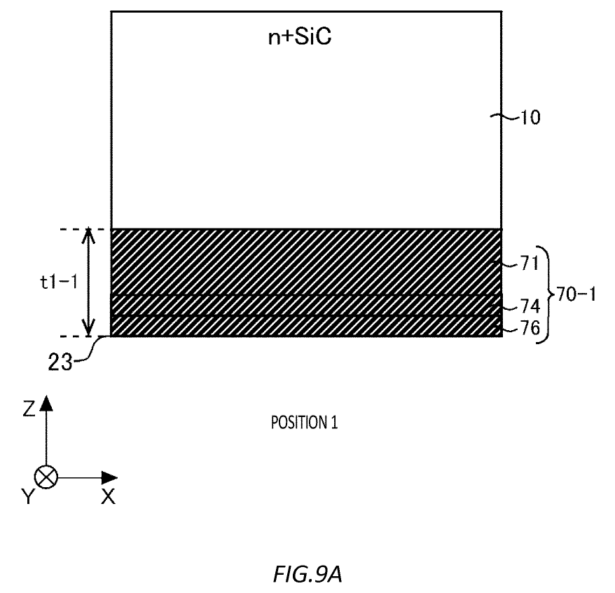

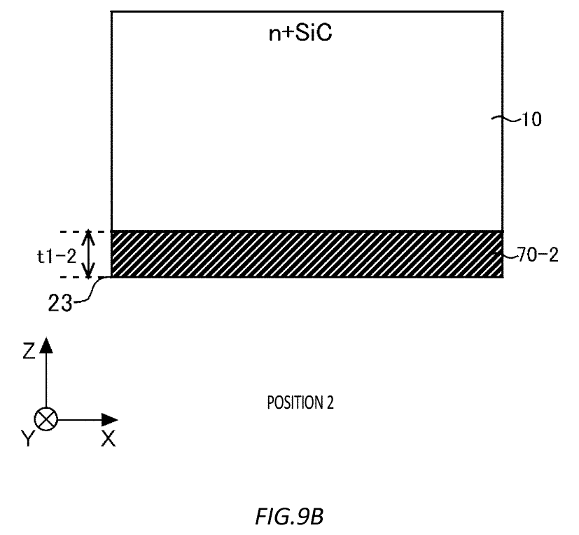

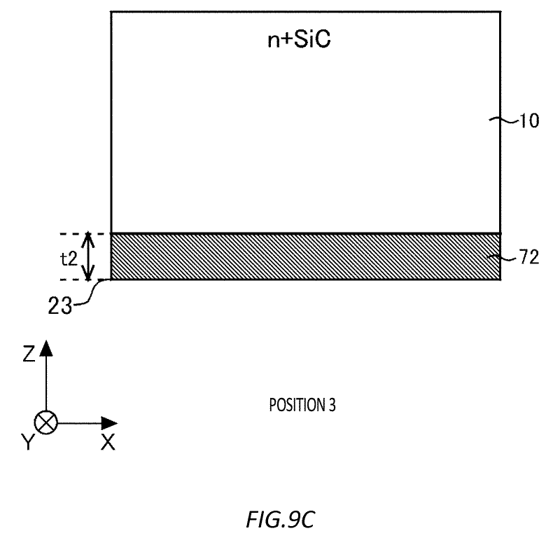

FIG. 9A is an example of a cross-sectional view at a position 1 in the vicinity of the lower surface 23 in FIG. 8. The position 1 indicates the vicinity of the center position of the laser radiation, and indicates the lower surface region 70-1 in FIG. 8. In a cross section at the position 1, the semiconductor device 100 has the lower surface region 70-1. From the lower surface 23, the lower surface region 70-1 has a precipitation layer 76, an amorphous Si layer 74, and a 3C-SiC region 71.

The precipitation layer 76 is a layer including carbon precipitated on the surface of the lower surface 23. The precipitation layer 76 may include amorphous SiC. The precipitation layer 76 has a thickness of about 10 nm as an example. The amorphous Si layer 74 has a thickness of about 15 nm as an example. These layers may be removed in the surface etching step S1006 described above. In addition, when these layers are thin, the lower surface electrode 64 may be formed at surfaces of the layers. The 3C-SiC region 71 is a region in which the crystal structure is the 3C-SiC crystal structure.

A thickness of the lower surface region 70 in the depth direction at the position 1 is set as a t1-1. The thickness t1-1 may be 10 nm or more and 500 nm or less. As described above, when the thickness t1-1 becomes smaller than 10 nm, it is not possible to form the ohmic contact. On the other hand, an upper limit of the thickness t2 is defined by the thickness t1 of the crushed layer 72. The thickness t2 may be 30 nm or more, or may be 50 nm or more, and may be 100 nm or less, or may be 200 nm or less.

FIG. 9B is an example of a cross-sectional view at a position 2 in the vicinity of the lower surface 23 in FIG. 8. The position 2 indicates the periphery of the position of the laser radiation. In a cross section at the position 2, the semiconductor device 100 has the lower surface region 70-2. In the present example, the lower surface region 70-2 does not have the precipitation layer 76 and the amorphous Si layer 74, and is exposed on the lower surface 23.

A thickness of the lower surface region 70 in the depth direction at the position 2 is set as a t1-2. The thickness t1-2 may be 10 nm or more and 500 nm or less. The thickness t1-2 may be 20 nm or more, or may be 30 nm or more, and may be 50 nm or less, or may be 100 nm or less. The thickness t1-2 at the position 2 may be smaller than the thickness t1-1 at the position 1.

The thickness t2 may be three times or less of a thickness t2'. This makes it possible to form the uniform ohmic contact.

FIG. 9C is an example of a cross-sectional view at a position 3 in the vicinity of the lower surface 23 in FIG. 8. The position 3 indicates an outside of the laser radiation mark. In a cross section at the position 3, the semiconductor device 100 does not have the lower surface region 70, and has the crushed layer 72 which is exposed on the lower surface 23. That is, at the position 3, a change in crystal structure from the crushed layer 72 to 3C-SiC does not occur. The thickness t2 of the crushed layer may be equal to the thickness t1-1 or the thickness t1-2, or may be greater than the thickness t1-1 or the thickness t1-2.

While the embodiments of the present invention have been described, the technical scope of the present invention is not limited to the above-described embodiments. It is apparent to persons skilled in the art that various alterations or improvements can be added to the above-described embodiments. It is also apparent from the described scope of the claims that the embodiments to which such alterations or improvements are added can be included in the technical scope of the present invention.

Note that the operations, procedures, steps, stages, or the like of each process performed by a device, system, program, and method shown in the claims, embodiments, or diagrams can be performed in any order as long as the order is not indicated by "prior to," "before," or the like and as long as the output from a previous process is not used in a later process. Even if the process flow is described using phrases such as "first" or "next" in the claims, embodiments, or diagrams, it does not necessarily mean that the process must be performed in this order.

What is claimed is:

1. A semiconductor device comprising:
a SiC substrate which has an upper surface and a lower surface;
an element structure which is formed on the upper surface of the SiC substrate;
a lower surface region which is exposed on at least a part of the lower surface of the SiC substrate, and which has a crystal structure different from that on an upper surface side; and
a lower surface electrode which is in contact with the lower surface of the SiC substrate, in a region including at least the lower surface region, wherein
the lower surface region includes 3C-SiC, and
a silicide layer is not formed between the lower surface electrode and the lower surface of the SiC substrate.

2. The semiconductor device according to claim 1, wherein
the lower surface region is exposed over the entire lower surface of the SiC substrate.

3. The semiconductor device according to claim 1, wherein
a crystal structure of the SiC substrate on the upper surface side relative to the lower surface region includes a 4H-SiC crystal structure.

4. The semiconductor device according to claim 1, further comprising:
a crushed layer which is exposed on at least a part of the lower surface of the SiC substrate.

5. The semiconductor device according to claim 4, wherein
an area of the crushed layer which is exposed on the lower surface of the SiC substrate is smaller than an area of the lower surface region which is exposed on the lower surface of the SiC substrate.

6. The semiconductor device according to claim 1, wherein
a thickness of the lower surface region in a depth direction is 10 nm or more and 500 nm or less.

7. The semiconductor device according to claim 1, wherein
a maximum value of a thickness of the lower surface region in a depth direction is three times or less of a minimum value of the thickness.

8. The semiconductor device according to claim 1, wherein
Ni is not present in a portion in contact with the lower surface region.

9. A method for manufacturing a semiconductor device comprising:
performing back grinding on a lower surface of a SiC substrate, and thinning the SiC substrate; and
performing laser annealing on a crushed layer generated by the back grinding to cause crystallization, and forming a lower surface region including 3C-SiC; and
forming a lower surface electrode at the lower surface region.

10. The method for manufacturing a semiconductor device according to claim 9, wherein
a thickness of the crushed layer before performing the laser annealing is 100 nm or more and 500 nm or less.

11. The method for manufacturing a semiconductor device according to claim 9, wherein
laser intensity in the laser annealing is 2.4 J/cm² or more and 3.0 J/cm² or less.

12. The semiconductor device according to claim 2, further comprising:
a crushed layer which is exposed on at least a part of the lower surface of the SiC substrate.

13. The semiconductor device according to claim 3, further comprising:
a crushed layer which is exposed on at least a part of the lower surface of the SiC substrate.

14. The semiconductor device according to claim 2, wherein
a thickness of the lower surface region in a depth direction is 10 nm or more and 500 nm or less.

15. The semiconductor device according to claim 3, wherein
a thickness of the lower surface region in a depth direction is 10 nm or more and 500 nm or less.

16. The semiconductor device according to claim 2, wherein
a maximum value of a thickness of the lower surface region in a depth direction is three times or less of a minimum value of the thickness.

17. The semiconductor device according to claim 3, wherein
a maximum value of a thickness of the lower surface region in a depth direction is three times or less of a minimum value of the thickness.

18. The semiconductor device according to claim 2, wherein
Ni is not present in a portion in contact with the lower surface region.

19. The semiconductor device according to claim 3, wherein
Ni is not present in a portion in contact with the lower surface region.

20. The method for manufacturing a semiconductor device according to claim 10, wherein
laser intensity in the laser annealing is 2.4 J/cm² or more and 3.0 J/cm² or less.
